(19) United States
(12) Patent Application Publication
(10) Pub. No.: US 2026/0353586 A1
(43) Pub. Date: Nov. 5, 2026

(54) BLIND CIRCUIT BOARD CONNECTIONS

(71) Applicant: Nvidia Corporation, Santa Clara, CA (US)

(72) Inventors: Karl Joseph Bois, Fort Collins, CO (US); Michael David Herring, Apex, NC (US); John Andrew Norton, Houston, TX (US); Joseph Michael Gallo, Littleton, MA (US)

(21) Appl. No.: 19/228,502

(22) Filed: Jun. 4, 2025

Related U.S. Application Data
(60) Provisional application No. 63/798,444, filed on May 1, 2025.

(51) Int. Cl. H05K 7/14; H05K 1/02

(52) U.S. Cl. CPC H05K 7/1487; H05K 1/02; H05K 2201/10409

(57) ABSTRACT

Systems and methods disclosed herein are for circuit board assembly which may include a printed circuit board (PCB) having at least two layers and a blind fastener capability provided, at least in part, by a hole through at most a first one of the at least two layers. The hole may be of a predetermined dimension to receive a blind fastener associated with an external component or connector and to allow the blind fastener to be anchored therein. A second one of the at least two layers may include one or more of a circuit component, an interconnect, or a further blind fastener capability which is through at most the second one of the at least two layers. The circuit component, the interconnect, or the further blind fastener capability may be in an unused area that is in an opposite or offset position from the hole.

### CROSS-REFERENCE TO RELATED APPLICATION(S)

This is a non-provisional application that is related to and that claims the benefit of priority from U.S. provisional patent application Ser. No. 63/798,444, filed May 1, 2025, and entitled “BLIND CIRCUIT BOARD CONNECTIONS,” the entire contents of which is incorporated by reference herein and form a part of this specification for all intents and purposes.

### TECHNICAL FIELD

At least one aspect herein pertains generally to circuit board connectors and, specifically, pertains to blind connections within circuit boards.

### BACKGROUND

A circuit board, such as a printed circuit board (PCB), may have a receiving connector and may be associated with a drilled through-hole. A through-hole may require access to both sides of the PCB and takes up usable area of the PCB.

### BRIEF DESCRIPTION OF THE DRAWINGS

Various embodiments in accordance with the present disclosure will be described with reference to the drawings, in which:

FIG. 1A illustrates a cross-section view of a circuit board assembly having blind circuit board connections, in accordance with at least some embodiments;

FIG. 1B illustrates a cross-section view of stages of a circuit board assembly having blind circuit board connections, in accordance with at least some embodiments;

FIG. 1C illustrates another cross-section view of stages of a circuit board assembly having blind circuit board connections, in accordance with at least some embodiments;

FIG. 1D illustrates a cross-section view a circuit board assembly having rivet-screw style blind circuit board connections, in accordance with at least some embodiments;

FIG. 1E illustrates another cross-section view of a circuit board assembly having interference-fit connectors for removable blind circuit board connections, in accordance with at least some embodiments;

FIG. 1F illustrates another cross-section view of a circuit board assembly having deformable pins for blind circuit board connections, in accordance with at least some embodiments;

FIG. 2A illustrates a connection between two circuit boards and used for signaling by blind circuit board connections, in accordance with at least some embodiments.

FIG. 2B illustrates a connector between a daughter board and a backplane or a midplane, in accordance with at least some embodiments;

FIG. 3A illustrates a process or method for blind circuit board connections, in accordance with at least some embodiments;

FIG. 3B illustrates a process or method for blind circuit board connections, in accordance with at least some embodiments;

FIG. 4 illustrates an example datacenter to apply at least one embodiment for power connection in FIGS. 1A-3B and 5-7;

FIG. 5 illustrates aspects of an example rack to apply at least one embodiment in FIGS. 1A-4 and 6A-7;

FIG. 6A illustrates an example datacenter system, according to at least some embodiments;

FIG. 6B is a block diagram that schematically illustrates a computing system that may be a datacenter or a High-Performance Computing (HPC) cluster, in which at least one embodiment described herein may be used;

FIG. 6C illustrates a computer system, according to at least one example, in which at least one embodiment described herein may be used; and

FIG. 7 illustrates an example network configuration of components that can be used to implement aspects of various embodiments, such as to provide, generate, modify, encode, process, fuse, and/or transmit generated image data, calculated measurements, or other such content.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

One example of an external connector may be a lead frame connector. Another example of the external connector may be a power connector. A lead frame connector may be a bridge connector that may be used between circuit boards (also referred to herein as printed circuit boards (PCBs)). A power connector may be used to provide power to a PCB and to its components. The PCBs may be daughter boards (or cards) and backplanes or midplanes of a rack in a datacenter. In one example, each lead frame connector may include multiple pins and each of the multiple pins may be used for differential signaling.

A circuit board assembly may include a PCB with blind fastener capability provided within at least two layers of the PCB to associate with external components or to make up electrical connections with external connectors. The external components may be able to perform a workload for a datacenter, in one example, and may include at least processors, memory, and switches, in some examples. One broadest example of the blind fastener capability is a hole of predetermined size and only extending through one of the at least two layers—and not through the entire PCB. In another example, the blind fastener capability may be provided by embedding a threaded component within layers of the PCB to receive studs or pins of an external connector within the PCB instead of leaving the pins or the external connector floating. The PCB may be a sequentially laminated PCB and anchoring using the blind fastener capability may provide additional support for each of the pins. In one example, the blind fastener capability allows the pins to be held in place and, by extension, allow the external connector to also be held in place, without need for designated screws or studs through the PCB. In another example, a stud or other threaded fastener may be threaded into threaded component of the blind fastener capability to anchor an external connector. In another example, a rivet-screw may be used within the blind fastener capability. The screw threads of a rivet-screw may allow mounting within a non-threaded hole of the blind fastener capability in the PCB. The rivet-screw may allow an interference-fit between the rivet-screw and the PCB using threads that may be expanded, by a tool, into a blind or non-threaded hole provided by the blind fastener capability in the PCB. The rivet-screw taps into blind vias and create an interference fit, providing mechanical fastening without through holes. In yet another example, the threaded component may allow a threaded fastener and a related component to be secured to the PCB.

A problem addressed is that a through-hole may affect every layer of a PCB. The through-hole may also support a screw that passes through the top surface or a bottom surface. Further, an exterior nut or threaded stud may be applied to the screw to affix an external component to the PCB. Another through-hole feature may be the use of spring beam ties that may pass into a through-hole of the PCB and may be used to grip an outside opposite surface or to friction fit within the through-hole. Yet another through-hole feature may be a metal post for soldering to provided aspects of the PCB for mechanical retention.

Another problem addressed is that, as a number of processors, such as graphics processing units (GPUs), inside a rack increases, there may be challenges associated with connecting the GPUs. There may be requirements to connect signals together using copper traces inside layers of the PCB which terminate at a PCB footprint. A surface mounted connector added to the PCB may provide the board-to-board connectivity but with an increase in size and number of such connectors, there not be room in at least the PCB footprint. In addition, mounting screws which mount a connector to a PCB may take usable area of the PCB—both on a surface of the PCB and by through-holes in the PCB, which may cause signal routing issues.

A difference allowed by the blind fasteners and blind fastener capabilities herein is an ability to allow a serviceable mechanical fastener to be used within the blind hole of a PCB without requiring through-hole vias, improving routing density and reducing layer count. The blind fastener capabilities may allow only one side of the PCB to be impacted by a fastener associated to a blind fastener capability. The ability to leave layers of the PCB or another side of the PCB free from fastening or through-hole aspects provides more usable area in the other adjacent layers, sub-laminates, or sides of the PCB. In addition, the blind fastener capability herein also removes mechanical obstruction of connectors for dual sided implementations such as midplanes. Removal of the obstructions also increases a mechanical density of fasteners allowed on a PCB.

The systems and methods described herein may be used for a variety of purposes, by way of example and without limitation, for machine control, synthetic data generation, model training or updating, perception, augmented reality, virtual reality, mixed reality, robotics, security and surveillance, simulation and digital twinning, autonomous or semi-autonomous machine applications, deep learning, environment simulation, object or actor simulation and/or digital twinning, datacenter processing, conversational artificial intelligence (AI), generative AI with large language models (LLMs), light transport simulation (e.g., ray-tracing, path tracing, etc.), collaborative content creation for 3D assets, cloud computing and/or any other suitable applications.

Disclosed examples herein may be comprised in a variety of different systems such as, systems for performing deep learning operations, systems for performing simulation operations, systems for performing digital twin operations, systems implemented using an edge device, systems incorporating one or more virtual machines (VMs), systems for performing synthetic data generation operations, systems implemented at least partially in a datacenter, systems for performing conversational AI operations, systems for performing generative AI operations using LLMs, systems for performing light transport simulation, systems for performing collaborative content creation for 3D assets, systems implemented at least partially using cloud computing resources, and/or other types of systems.

In one example, computing devices or components on a PCB benefiting from the lead frame connectors herein may include processors of different types. The processors may include central processing units (CPUs), graphics processing units (GPUs), data processing units (DPUs), quantum processing units (QPUs), parallel processing units (PPUs), and application-specific integrated circuits (ASICs). QPUs may be configured to perform one or more operations associated with a quantum algorithm. In some examples, each of the one or more QPUs may include qubits. One or more QPUs may be in communication with each other via a quantum channel. In some examples, each of the qubits may include local qubits, global qubits, and/or synchronization qubits. In some examples, the local qubits of each QPU may be configured to perform the one or more operations associated with the quantum algorithm on the QPU that are associated with the local qubits.

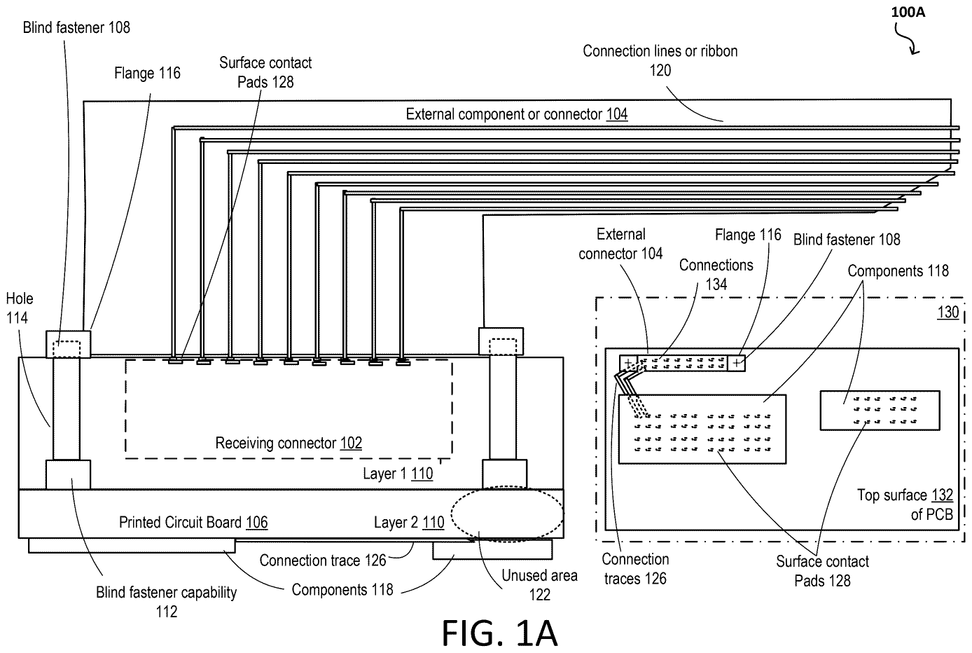

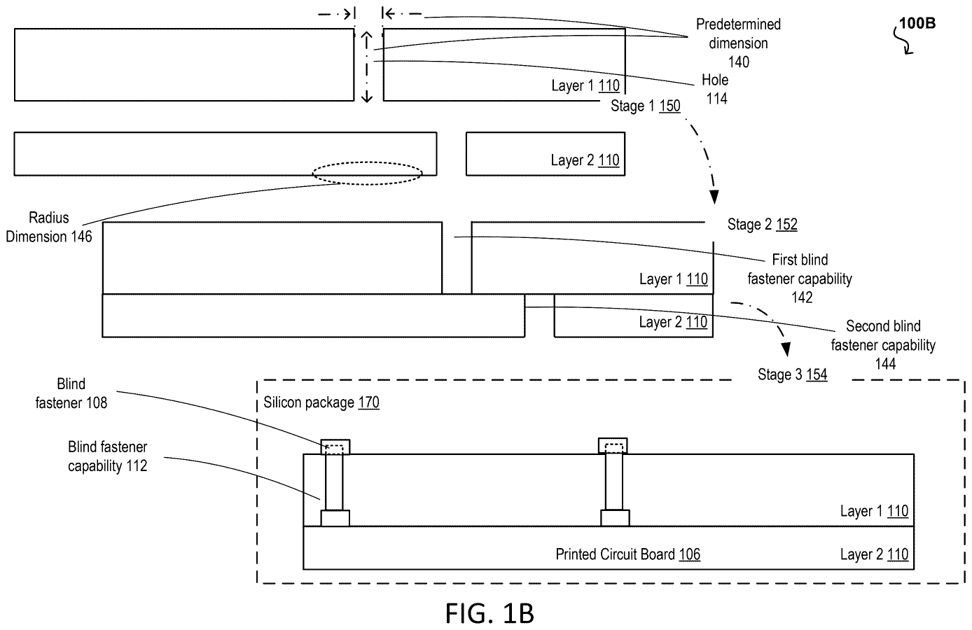

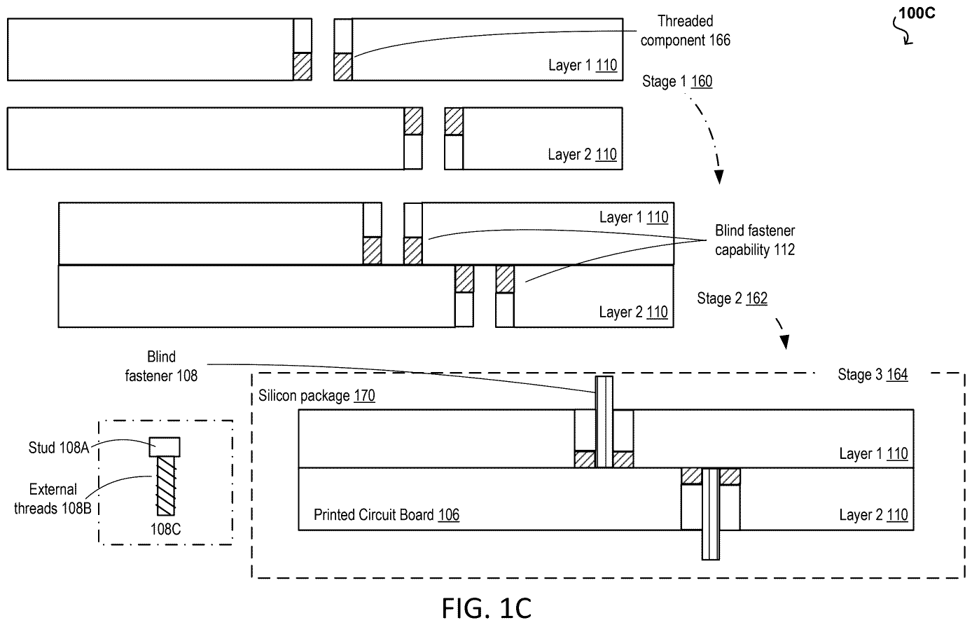

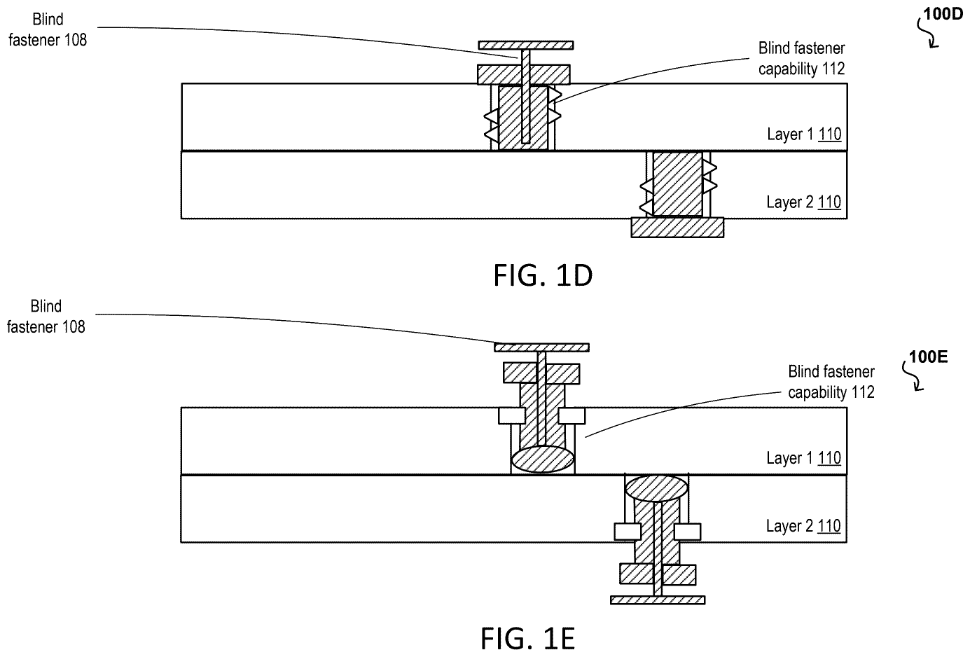

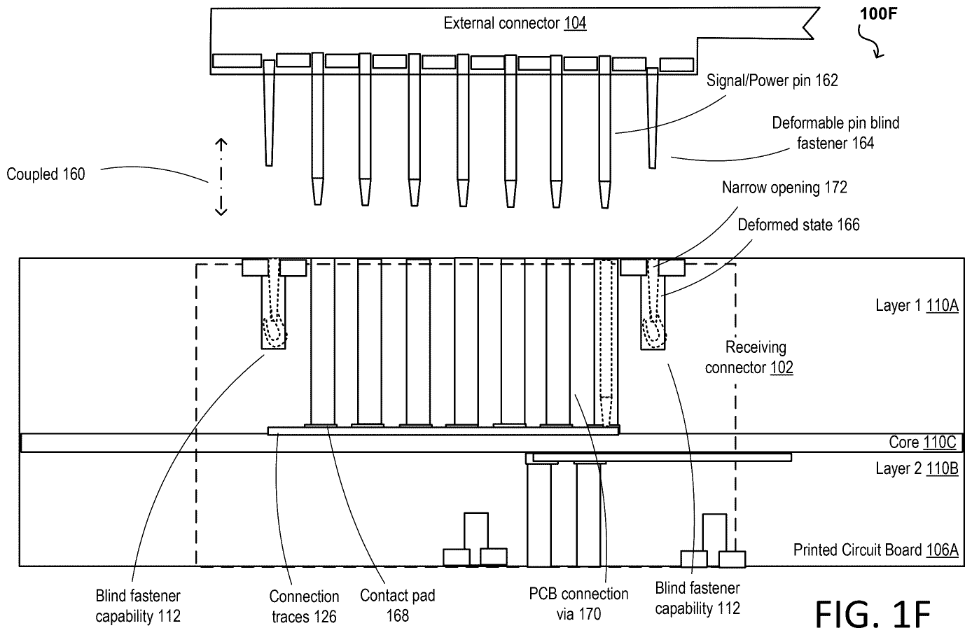

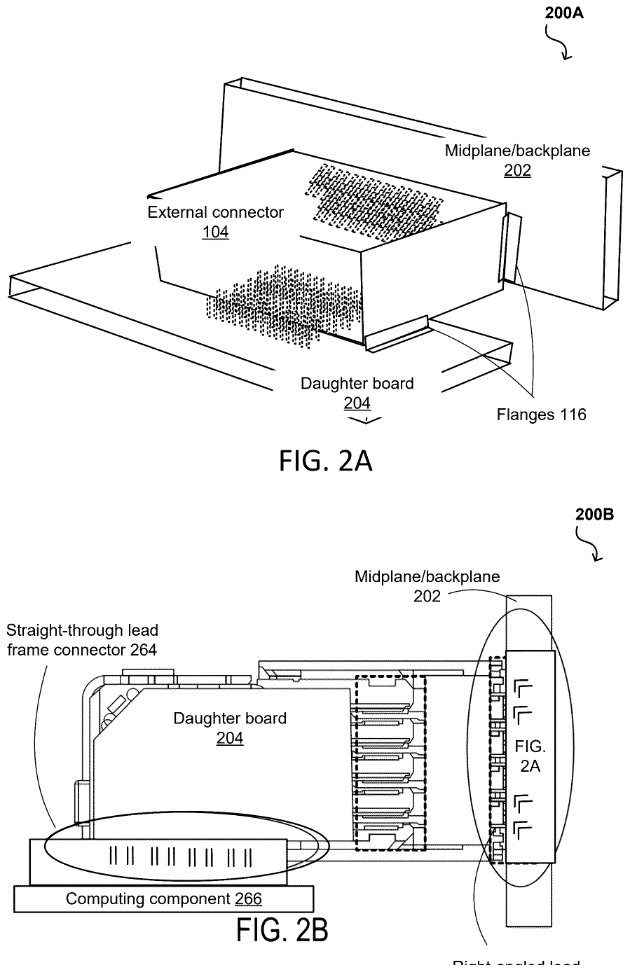

FIG. 1A illustrates a cross-section view 100A of a circuit board assembly having blind circuit board connections, in accordance with at least some embodiments. The circuit board assembly may include a PCB 106 having at least two layers 110. The two layers are marked as layer 1 and layer 2 for illustrative purposes. The PCB 106 may include a blind fastener capability 112 provided, at least in part, by a hole 114 (also referenced herein as a blind hole) through at most a first one (such as layer 1) of the at least two layers 110. The hole 114 may be of a predetermined dimension (such as illustrated in FIG. 2B) to receive a blind fastener 108 associated with an external component or connector 104. The external component or connector 104 may include further connection lines or ribbon 120 to transmit signals internally, once received to the external component or connector 104. In one example, the hole 114 may be formed as part of the layers 110 of the PCB. In some examples, the hole 114 may be drilled into the PCB 106.

The hole 114 may allow the blind fastener 108 to be anchored therein. A second one (such as layer 2) of the at least two layers 110 may include one or more of a circuit component 118, a connection trace 126, or a further blind fastener capability (such as a second blind fastener capability 144 in FIG. 2B). As used herein, a connection trace 126 or any physical conductive feature of a PCB 106 which allows transmission of power or signals may from an interconnect. The interconnect may be a copper clad or copper line at a surface or between layers 110A, 110B of a PCB 106. The further blind fastener capability may be through at most the second one (such as layer 2) of the at least two layers 110. The circuit component 118, the connection trace 126, or the further blind fastener capability 144 may be in an unused area 122 that is in an opposite or offset position from the hole 114. As used herein, an opposite position may be in reference to a position that is directly opposite the hole 114 and accessible from an opposite side of the PCB 106, relative to a side of the PCB 106 having the hole 114. As used herein, an offset position may be in reference to a position that is on the opposite side of the PCB 106 and is indirectly opposite the hole 114. For instance, the offset position may also be accessible from the opposite side of the PCB 106, but also offset from the hole 114, relative to the side of the PCB 106 having the hole 114.

The circuit board assembly may be such that the blind fastener capability 112 may define the unused area 122 in the opposite or offset position from the hole based in part on a radius dimension (such as in FIG. 1B). The radius dimension may be a surface or below surface dimension of an area that is away from the hole 114 of the blind fastener capability 112. The unused area 122 may be on a surface of the second one (such as layer 2) of the at least two layers 110. For instance, the surface may be an opposite side of the first one (such as layer 1) of the two layers 110. The unused areas 122 may be through the surface of the second one of the at least two layers 110, in some examples. The unused area 122 may be between the at least two layers 110 of the PCB 106, in some examples.

The circuit board assembly may be such that the blind fasteners 108 allow an external component or connector 104 to be coupled to the PCB 106. For example, the blind fasteners 108 may be through flanges 116 on the sides of the external component or connector 104 to hold the external component or connector 104 against the PCB 106. This hold may allow connections 134 between pins or pads of the external component or connector 104 against surface contact pads 128 of the receiving connector 102 on the PCB 106. In some examples, the blind fasteners 108 may be part of the external component or connector 104 at its flanges 116. In some examples, the blind fasteners 108 may be separate from the flanges 116 and may be associated to the flanges 116 when the hold is required between the external component or connector 104 and the PCB 106. There may be connection traces 126 between the receiving connector 102 and other surface contact pads 128 of the components 118, as illustrated in the callout 130 illustrating a section of a top surface 132 of the PCB 106.

FIG. 1B illustrates a cross-section view 100B of stages of a circuit board assembly having blind circuit board connections, in accordance with at least some embodiments. The stages 150-154 may be associated with a method for an electrical connection, such as between a PCB 106 and an external component or connector 104. A first stage 150 may include preparing a PCB 106 to include at least two layers. The first stage 150 may include determining a hole 116 of a predetermined dimension to receive a blind fastener associated with an external component or connector. The first stage 150 may include forming a blind fastener capability based at least in part by the hole being provided through at most a first one of the at least two layers.

In one example, the PCB 106 may be a multi-layer PCB having an inner layer core formed of one or more of plastic, epoxy, or fiberglass. In some examples, thin sheets of fiberglass epoxy laminate (such as FR-4) may be used. In some examples, the sheets may be clad with copper foil on one or both sides providing inner layers for connection traces or interconnection. Photo-etching may be performed using a photoresist applied to thin sheets. A phototool may be placed over the photoresist and the thin sheets may be exposed to high-intensity ultraviolet (UV) light to harden the photoresist in the areas to be maintained as the connection traces or the interconnects and as the surface contact pads. The unhardened photoresist may be removed to expose other areas of copper. A chemical etching may be formed over the exposed other areas to remove the unwanted copper. The etching may be also performed for the holes 114 to form the blind fastener capability 112 in each of the sheets. A stacking and bonding (such as by lamination) may pe performed to the sheets as part of a stage two 152 of the stages of a circuit board assembly having blind circuit board connections.

In some examples, in the stacking and bonding performed, the multiple layers may be combined in an intended order so that unused areas are at least opposite or offset position from the hole of a prior layer. In some examples, the sheets may include a fiberglass cloth impregnated with partially cured epoxy resin placed between layers to provide an insulating glue. The stacked layers may be placed into a lamination press. Under pressure and high temperature, the resin from the insulating glue may flow and fill gaps in the layers. The resin may cure to bond the entire stack into a single solid multi-layer board having the blind fastener capability 112 in one or more of the layers.

In some examples, stage one 150 and stage two 154 may result in only a laminated and stacked layers of a PCB. Then, drilling may be performed after the PCB 106 is formed as a multi-layer PCB and as part of one or more of the first and second stages 150, 154. For instance, with the layers bonded, the holes 114 may be are drilled through the laminated layers but through at most one layer of at least two layers. The holes 114 may be from one side and may serve two the purpose of providing further aspects of the blind fastener. The drilling may be performed using computer-controlled drills. The holes may be cleaned to prepare for further processing.

In one example, a stage three 154 may include allowing one or more blind fasteners 108 to be anchored into the blind fastener capabilities 124 prepared in stages one or two 150, 152. In one example, a second one (such as layer 2) of the at least two layers 110 may be allowed to include one or more of a circuit component, an interconnect, or a further blind fastener capability which is through at most the second one of the at least two layers. In addition, the circuit component, the interconnect, or the further blind fastener capability may be such that it is in the unused area, such as defined by the radius dimension 146, and that is in an opposite or offset position from the hole 114. In some examples, the radius dimension 146 may be part of a determining step in stages one or two 150, 152, for defining the unused area 122 intended for the circuit board assembly. The defining of the unused area 122 for each blind fastener capability 124 may be planned such that it is in the opposite or offset position from respective holes 114 and based in part on the radius dimension 146 that is also away from the hole. In some examples, the unused area 122 may be on a surface of the second one of the at least two layers 110, may be through the surface of the second one of the at least two layers 110, or may be between the at least two layers 110 of the PCB 106.

FIG. 1C illustrates another cross-section view 100C of stages of a circuit board assembly having blind circuit board connections, in accordance with at least some embodiments. As illustrated, relative to FIG. 1B, the stages 160-164 may be used to provide a circuit board assembly with threaded component 166 that is embedded between the at least two layers 110 of the PCB 106. The threaded component 166 may form a further part of the blind fastener capability 112. In one example, as illustrated in callout 108C, a stud 108A having external threads 108B may form the blind fastener 108 and may be fastened into the threaded component 166 to allow the blind fastener 108 to be anchored in the blind fastener capability 112.

Stage one 160 may be similar to stage one 150 in FIG. 1B. In addition, however, different sizes holes may be provided in the layers so as to be able to provided the threaded component 166 within a wider dimensioned hole and which is to be laminated and bonded against an enclosing surface of another layer of the multi-layer PCB. In one example, the threaded component 166 may be provided within the lamination and bonding performed in the stage two 164 part of the process or method to form a circuit board assembly having blind circuit board connections. The threaded component 166 may be formed of one or more of the materials used to form the PCB 106. In some examples, other materials, including metals may be used to form the threaded component 166.

In some examples, the threaded component 166 may be other mechanical fasteners capable of retaining a blind fastener. The stages for providing the threaded component 166 may also include counterboring as a step to be done to use the material of the PCBs itself as a threaded component 166 or to embed a threaded component 166 into the PCB. At least parts of stage two 152, 162 in both FIGS. 1B, 1C may be a sequential laminated process. The threaded component 166 may be a thread-cutting screw in some examples. As detailed further in regard to at least FIGS. 1D and 1E, the threaded component 166 may be an interference-fit rivet-screw. As illustrated, each of the multiple layers 110 may include a respective threaded component 166. In addition, as illustrated in FIGS. 1B, 1C, the PCB 106 may be part of a silicon package 170 with multiple dies forming the components 118.

As illustrated, the blind circuit board connections may be provided for any coupling to make a suitable contact for a specific format of a connection, such as NVLINK5 connection from Nvidia®. In another example, the connectors herein may support different media of transmission. A medium of transmission as used herein may allow networking capabilities associated with direct attach copper (DAC), active copper cable (ACC), active optical cables (AOCs), cable assembly with OSFP connectors or the like) or interconnect utilized by switch modules (including PCB connectors forming a board-to-board connection or a cabled header forming a board-to-cabled connection). The network connectors may each be configured to connect to a networking device of any type (e.g., QSFP, Direct Attach Copper, active optical cables (AOC), etc.), and may thus be dimensioned (e.g., sized and shaped) to mate with or otherwise connect to any corresponding networking device. The cable connector may be of any type (e.g., an AOC connector, Ethernet connector, Direct Attach Copper connector, Active Optical Module, or the like). A PCB is used to electrically connect electronic components using conductive pathways, or traces, etched from metal sheets. In many electronic systems, one or more very large-scale integrated circuit (“VLSI”) components are coupled to a host system printed circuit board (“PCB”). Such VLSI components may include, for example, central processing unit (“CPU) devices and graphics processing unit (“GPU”) devices. The PCB may hold at least one processing circuitry. The processing circuitry may comprise hardware, such as an application specific integrated circuit (ASIC). The processing circuitry may comprise an ASIC and/or may be capable of performing as a central processing unit (CPU), a graphics processing unit (GPU), a network interface controller (NIC), a data processing unit (DPU), or any other computing device in which with data is received and/or transmitted. Other non-limiting examples of the processing circuitry include an Integrated Circuit (IC) chip, a Central Processing Unit (CPU), a Graphics Processing Unit (GPU), a microprocessor, a Field Programmable Gate Array (FPGA), a collection of logic gates or transistors, resistors, capacitors, inductors, diodes, or the like. It should be appreciated that any appropriate type of electrical or optical component or collection of electrical or optical components may be suitable for inclusion in the processing circuitry. Numerous example embodiments will be described below in which a semiconductor package is mounted within a blind hole of a PCB. Although PCBs having certain types and form factors appear in the drawings and the discussion, it should be noted that the illustrated and described types and form factors are provided by way of example only. Persons having skill in the art and having reference to this disclosure will readily appreciate that the same or similar apparatus and techniques may also be employed with PCBs having other types and form factors. For example, in some embodiments, the PCB to which the semiconductor package is mounted may comprise an add-in card, such as a PCIe card, that is configured to be coupled to a system board or motherboard of a host system. In other embodiments, the PCB to which the semiconductor package is mounted may be the system board or motherboard of the host system itself. Moreover, the system board or the motherboard may be associated with any type of host system. For example, the PCB may comprise the system board in a multi-node rack-mounted server, or it may comprise the motherboard of a workstation, desktop, laptop, or mobile device. Other embodiments are also possible.

FIG. 1D illustrates a cross-section view 100D a circuit board assembly having rivet-screw style blind circuit board connections, in accordance with at least some embodiments. The rivet-screw may form a blind fastener capability 112 within a hole 114 of the PCB 106. The rivet-screw may be a rivet having threads and may be installed as a blind rivet from one or more sides of the layers of a PCB 106. The rivet-screw may have a hollow center to be used to receive a blind fastener 108. The rivet-screw may be installed using a tool to collapse, bulge, or dig against the material of the hole or the PCB 106, which secures it in place and allows it to receive the blind fastener 108.

FIG. 1E illustrates another cross-section view 100E of a circuit board assembly having interference-fit connectors for removable blind circuit board connections, in accordance with at least some embodiments. The interference-fit connector may also form a blind fastener capability 112 within a hole 114 of the PCB 106. The interference-fit connectors may be removable forms of the blind fastener capabilities 112 within respective ones of the holes 114 of the PCB 106. The interference-fit connector may be a rivet having threads and may be installed as a blind rivet from one or more sides of the layers of a PCB 106.

In one example, the interference-fit connector may include a shaft that may be dimensioned larger than a receiving feature. An initial dimension of the shaft may be larger than an initial dimension of a receiving feature, such as a diameter of a hole of the receiving feature. The shaft may be forced into the receiving feature and may be held in place by interference, press-fit, or friction. The force may cause a change in dimension of the shaft and lock it in place with the receiving feature. In some examples, thermal expansion may be used to return one or more of the shaft or the receiving feature to its initial dimension to remove the interference-fit connector from the hole and undo the blind fastener capability, at least in part. In some examples, pressure or compression may be used to allow the interference-fit. The interference-fit connector may also have a hollow center to be used to receive a blind fastener 108. The interference-fit connectors may be installed using a tool to also collapse or bulge, as part of the interference-fit, against the material of the hole or the PCB 106. This may secure the interference-fit connectors in place and allow it to receive respective blind fasteners. In addition, the interference-fit connectors may be removed by reversing the installation.

The circuit board assembly herein may be such that a threaded component that is embedded between the at least two layers of the PCB, as in FIG. 1D. The threaded component may form a further part of the blind fastener capability. A stud having external threads may form the blind fastener, as also discussed in connection to FIG. 1D, to fasten into the threaded component to allow the blind fastener to be anchored in the blind fastener capability. With respect to FIG. 1E, the material of the PCB 106 may allow the rivet-screw having an external thread to be received into the hole 114. The hole 114 being a non-threaded hole may hold the rivet-screw to form the blind fastener. The material of the PCB 106 may also allow the external thread of the rivet-screw to be expanded into sidewalls of the hole by circumferential expansion of the rivet-screw. The expansion into the sidewalls may allow the blind fastener to be anchored in the blind fastener capability. In addition, the rivet-screw may be removable by rotation of the external threw against the sidewalls of the hole.

The circuit board assembly may be such that it allows one or more deformable pins of an external connector to be used as the blind fastener 108. For example, the one or more deformable pins may be received into the blind fastener capability and may collapse once inside the blind fastener capability or the hole 114 forming the blind fastener capability 112, in at least one example. When collapsed within the blind fastener capability, the one or more deformable pins forms the blind fastener to hold an external component or connector 104 to the receiving connector 102. In each of FIGS. 1A-1E, the blind fastener and connection may occur through a flange 116, although it is possible to use some of the pins used for the connections 134 between the external component or connector 104 and the receiving connector 102 as the blind fastener and the blind fastener capability. The collapse of the pins, may, in some examples, allow the one or more deformable pins to be anchored within the blind fastener capability.

The circuit board assembly may be such that blind fastener is a removable or reusable fastener, allowing for connectors to be removed and replaced without damaging the PCB. The blind fastener capability may also be removable or reusable to receive the blind fastener and to allow the blind fastener to be anchored therein, as described in connection with at least FIG. 1E. The circuit board assembly may be such that the PCB 106 includes external connectors to the blind fastener capability on the first one of the at least two layers 110. The PCB 106 may include only the circuit components or the interconnects on the second one of the at least two layers 110, in some examples.

In at least some examples, the circuit board assembly may be such that PCB 106 is a dual-sided midplane. Then, the interconnects 126 may be copper connectors within the at least two layers 110 of the PCB 106. The circuit component 118 may be a GPU on the second one of the at least two sides 110 of the PCB 106. The copper connector and the GPU may be in the unused area 122, in at least some examples.

FIG. 1F illustrates another cross-section view 100F of a circuit board assembly having deformable pins for blind circuit board connections, in accordance with at least some embodiments. For instance, an external connector 104 may include signal and or power pins 162 (signal/power pins) and may include one or more deformable pin blind fasteners 164, also referenced herein as deformable pins. While the signal and or power pins 162 may be received through PCB connection vias 172 to contact pads 168 and connection traces 126 of the receiving connector 102, the one or more deformable pins blind fasteners 164 may be received into respective blind fastener capabilities 112, when the external connector 104 is coupled 160 to the receiving connector 102. The receiving connector 102 is illustrated as on both sides of a multi-layer PCB 106A. The multi-layer PCB 106A may include a core 110C, a layer 1 110A, and a layer 2 110B. The layer 1 110A and the layer 2 110B may be copper clad or copper comprised layers which may include connection traces 126 and contact pads 168. The core 110C may be an insulating layer.

The deformable pins blind fasteners 164, once received into the respective blind fastener capabilities 112, may collapse to a deformed state 166, at least in part, within the blind fastener capabilities 112. The one or more deformable pins blind fasteners 164 may form the blind fastener and the collapse to the deformed state 166 may allow the one or more deformable pins blind fasteners 164 to be anchored within the respective blind fastener capabilities 112. In some examples, in the deformed state 166, the deformable pins blind fasteners 164 may anchor into sidewalls of the respective blind fastener capabilities 112, similar to the description in connection with FIG. 1D. Also, in the deformed state 166, the deformable pins blind fasteners 164 may be deformed to the extent that they fill up the respective blind fastener capabilities 112 and are wedged and retained based in part on a narrow opening 172 of the respective blind fastener capabilities 112. This allows the external connector 104 to be retained with the receiving connector 102, using the deformable pins blind fasteners 164, in some examples. Another external connector may be received on an opposite side of the multi-layer PCB 106A and may also be retained by respective blind fastener capabilities 112 on that side.

FIG. 2A illustrates a connection 200A between two circuit boards and used for differential signaling by a lead frame connector, in accordance with at least some embodiments. One of the circuit boards may be a midplane or a backplane 202 and another one of the circuit boards may be a daughter board 204. The lead frame connector may be an external connector 104 with pins on either side to fit with the surface contact pads of the midplane or a backplane 202 and of the daughter board 204. When used as a blind fastener, the pins may deform and be held in place with at least corresponding blind fastener capabilities of the midplane or the backplane 202 and of the daughter board 204. As illustrated, the lead frame connector may be held down by flanges 116 on its ends, in some examples, and the use of blind fasteners and blind fastener capabilities associated with flanges 116.

The blind fasteners and the blind fastener capabilities may function to retain or restrict the lead frame connector from disconnection or movement away from a receiving connector 102 of a circuit board. On at least the daughter board 204, the receiving connector may be associated with surface contact pads of its components. On the midplane or the backplane, the surface contact pads may be aligned with its own receiving connector and to allow a connection from a lead frame connector to components between the midplane or a backplane 202 and the daughter board 204.

FIG. 2B illustrates a connection 200B between a daughter board and a backplane or a midplane and other computing components, in accordance with at least some embodiments. FIG. 2B illustrates the use of a right-angled lead frame connector 262 between a daughter board 204 and a midplane or backplane 202. The right-angled lead frame connector 262 may be as described in connection with FIG. 2A, and specifically, as to the lead frame connector in FIG. 2A. FIG. 2B also illustrates the use of a straight-through lead frame connector 264. The straight-through lead frame connector 264 may be provided between computing components 266 and the daughter board 204. The computing components may be adapters, memory sticks, communication cards, and others that may be intended for use with a daughter board 204 or the midplane or backplane 202, through the daughter board 204.

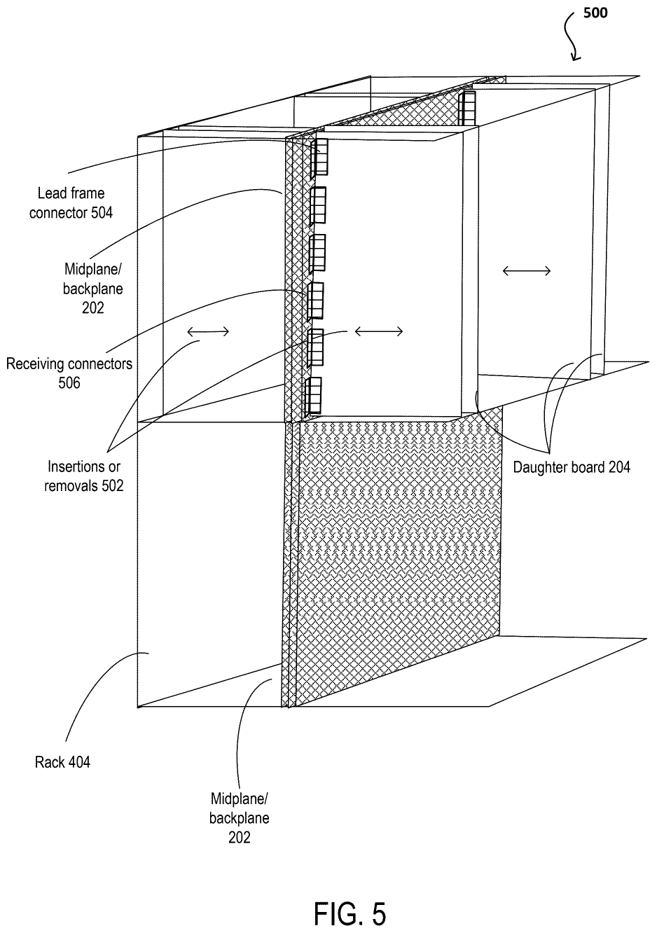

Each of the right-angled lead frame connector 262 and the straight-through lead frame connector 264 may include integration of the blind circuit board connections as part of its lead frame connector's pins and as part of the blind holes, as discuss in detail with one or more of FIGS. 1A-1C. In at least one example, some pins in each connector 104 of the right-angled lead frame connector 262 and the straight-through lead frame connector 264 may be used for blind circuit board connections. The midplane or a backplane 202 may belong to a rack in a datacenter, which is detailed further in at least FIG. 5.

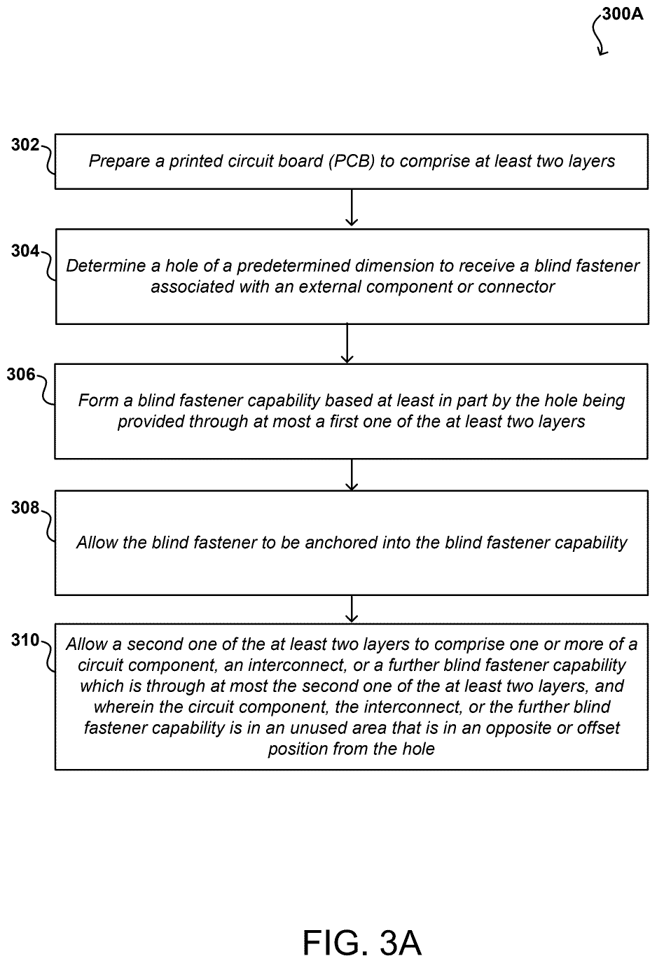

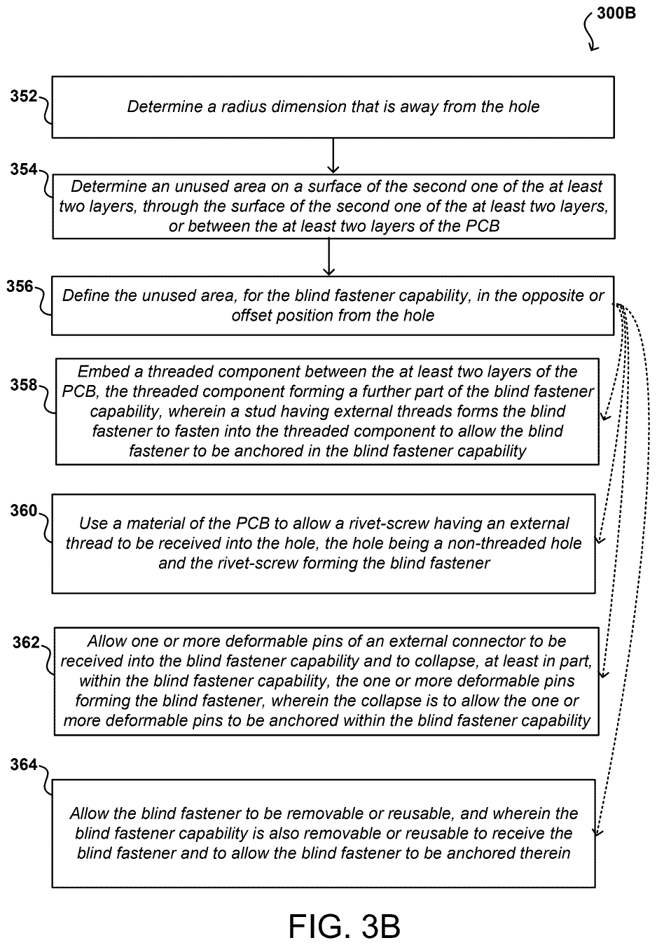

FIG. 3A illustrates a process or method 300A for blind circuit board connections, in accordance with at least some embodiments. For instance, the method 300A may include a step to prepare 302 a PCB to include at least two layers. The method 300A may include a step to determine 304 a hole of a predetermined dimension to receive a blind fastener associated with an external component or connector. The method 300A may include a step to form 306 a blind fastener capability based at least in part by the hole being provided through at most a first one of the at least two layers. The method 300A may include a step to allow 308 the blind fastener to be anchored into the blind fastener capability. The method 300A may include a step to allow 310 a second one of the at least two layers to include one or more of a circuit component an interconnect, or a further blind fastener capability which is through at most the second one of the at least two layers. The circuit component, the interconnect, or the further blind fastener capability may be in an unused area that is in an opposite or offset position from the hole.

FIG. 3B illustrates another process or method 300B for blind circuit board connections, in accordance with at least some embodiments. The method 300B in FIG. 3B may be used with the method 300A in FIG. 3A. The method 300B may provide a connector for signaling or power. The method 300B may include a step to determine 352 a radius dimension that is away from the hole. The method 300B may include a step to determine 354 an unused area on a surface of the second one of the at least two layers, through the surface of the second one of the at least two layers, or between the at least two layers of the PCB. The method 300B may include a step to define 356 the unused area, for the blind fastener capability, in the opposite or offset position from the hole.

The method 300B may include different or alternating steps to providing the blind fastener and the blind fastener capability, which may depend on the radius dimension and which may imply an application of the PCB. For instance, space required on a PCB, size of the PCB and the external component or connector, components of the PCB, or types of the external component or connector may be a basis to use one of the different blind fasteners or blind fastener capabilities herein. The method 300B may include a step to embed 358 a threaded component between the at least two layers of the PCB. The threaded component may form a further part of the blind fastener capability. A stud having external threads may form the blind fastener to fasten into the threaded component to allow the blind fastener to be anchored in the blind fastener capability. This allows for stronger retention between an external component or connector, with respect to the PCB, in one example.

The method 300B may include a step to use 360 a material of the PCB to allow a rivet-screw having an external thread to be received into the hole. The hole may be a non-threaded hole and the rivet-screw may form the blind fastener. The method 300B may include a step to allow 362 one or more deformable pins of an external connector to be received into the blind fastener capability and to collapse, at least in part, within the blind fastener capability. The one or more deformable pins forming the blind fastener. The collapse is to allow the one or more deformable pins to be anchored within the blind fastener capability. The method 300B may include a step to allow 364 the blind fastener to be removable or reusable. The blind fastener capability may also be removable or reusable to receive the blind fastener and to allow the blind fastener to be anchored therein

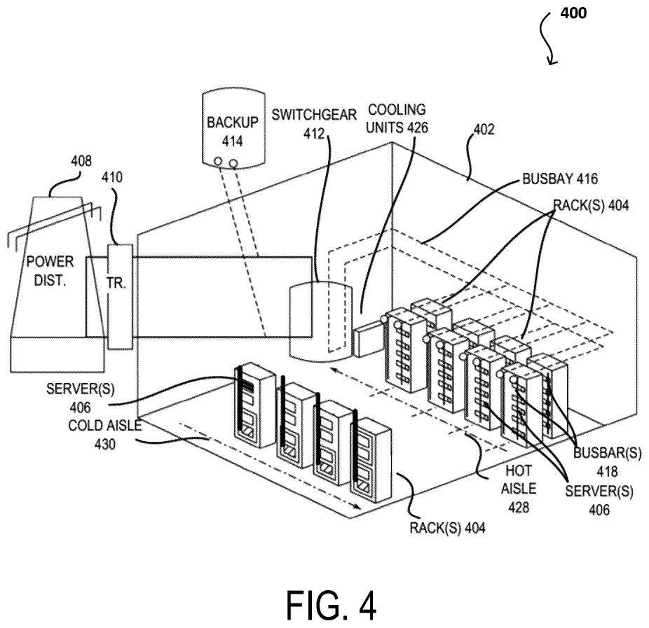

FIG. 4 illustrates an example datacenter to apply at least one embodiment for power connection in FIGS. 1A-3B and 5-7. The datacenter 400 may include racks 404 that may be associated with servers 406 therein (in a server tray, server box, or server/computer module format), and that may include compute devices therein to perform a workload. Although illustrated as horizontal features, the servers 406 may be vertically provided within a rack 404. Such racks 404 may be tied (such as hardwired or natively within rows of racks) as part of the infrastructure of the datacenter 400. For instance, the racks 404 may be associated with power supply units (PSUs) and may be associated with a busbay 416 to receive and distribute power for the servers 406, these racks 404 may necessarily include power components (such as busbars 418) that are intimately associated with the racks 404. The power components may be part of the infrastructure of the datacenter 400. The racks 404 may include high-speed interconnect, enabling high-speed communication between subsystems, including the servers 406.

The compute devices may be provided on circuit boards and may include processors (such as central processing units (CPUs), quantum processing units (QPUs), graphics processing units (GPUs), data processing units (DPUs), application-specific integrated circuits (ASICs), field-programmable gate arrays (FPGAs), physics processing units (PPUs), or the like), and other components (such as memory, communication modules, input/output modules, and the like).

In at least one embodiment, the datacenter 400 may include one or more rooms 402 of racks 404, where the racks 404 may include server trays or servers 406. The datacenter 400 may be powered from a power distribution 408 system, via one or more transformers 410 (Tr.), so that the power to a switchgear 412 may be suitable for the datacenter. For instance, the power distribution 408 system may be part of a transmission system. The transmission system may provide high-voltage electricity from a utility grid. Each transformer 410 may step down the voltage to a level suitable for the datacenter's equipment and devices, such as the aforementioned processors that may be in the server trays or servers 406 in each rack 404. The switchgear 412 may be able to control, protect, and isolate power in both downstream and upstream directions.

The switchgear 412 may be used to manage flow of electricity in a reliable and efficient manner using switching of electrical circuits for controls and using breakers and fuses to detect and respond to faults or overloads in both downstream and upstream directions. In addition to an external source represented by the transmission systems and to ensure uninterrupted power supply, a backup 414 system, such as a generator or Uninterruptible Power Supply (UPS), may be used with the power distribution 408 system (Power Dist.). In addition, a cooling unit 426 may provide at least air cooling for the cold aisle 430 side and pass through the racks 404 to the hot aisle 428 side of the datacenter 400. The movement of the air cooling may be supported by fans, in one example.

The switchgear 412 may be associated with the busbay 416. The busbay 416 may provide power to one or more racks 404. In one example, the busbay 416 may provide power to one or more racks 404 through provided busbars 418. The busbars 418 may be conductive bars that carry electrical current to various loads, including those represented by the aforementioned processors, which may be within the server trays or computer modules (also referenced as servers 406) in each rack 404 of the datacenter 400. The busbars 418 may be provided from copper, aluminum, or a suitable power delivery material. The busbars 418 may be able to work together to handle the high-current demands of the datacenter 400.

The datacenter 400 may include a midplane or a backplane 202, as in FIGS. 2A, 2B, and the related discussions. The midplane or the backplane 202 may have the surface contact pads to receive the lead frame connectors (such as the external connectors in FIGS. 1A-1C) between other circuit boards (such as the daughter boards 204 in FIGS. 2A and 2B) or from other components of the datacenter. These components may include power components as described herein and the computing components 266, as described in connection with FIG. 2B, for instance. The midplane or the backplane 202 may be associated with receiving connectors having blind fasteners to receive and hold lead frame connectors of the daughter boards 204, where multiple daughter boards 204 may be plugged into the midplane or backplane 202. There may be power connectors between one or more of the daughter boards 204 and the midplane or backplane 202. These connectors may be anchored between the daughter boards 204 and the midplane or backplane 202 using blind fasteners and using blind fastener capabilities described throughout herein.

FIG. 5 illustrates aspects 500 of an example rack to apply at least one embodiment in FIGS. 1A-4 and 6A-7. The aspects 500 illustrate that a rack 404 may have at least one circuit board that may be a midplane or a backplane 202. Although illustrated as open, the rack 404 may be fully enclosed with front, back, side, and top covers or access panels. Also, although illustrated at a high-level flat structure, the circuit board may include at least one PCB (also, as illustrated and described in at least FIGS. 2A and 2B). When used as a backplane, a circuit board may include a single side of receiving connectors 506 to receive lead frame connectors 504 of the daughter boards or cards 204. When used as a midplane, the circuit board may include two sides of receiving connectors 506 to receive lead frame connectors 504 of the daughter boards or cards 204 on both sides of the circuit board. In the aspects 500 in FIG. 5, the circuit board is a midplane which is located at a middle of a rack 404. The midplane may receive servers 406 in a vertical board format or daughter boards 204, which may be pushed for insertion 502 against the receiving connectors 506, for instance, of the midplane forming one or many connections between the midplane and the servers or the daughter boards 204.

FIG. 5, along with FIGS. 1A-1C also illustrate aspects 500 of a datacenter having a midplane or a backplane 202 and one or more daughter boards 204, along with blind fasteners used with the connectors (as in FIGS. 1A-1C). The midplane or a backplane 202 may include signal surface contact pads for differential signals and ground surface contact pads, channels, or lines. The midplane or a backplane 202 may include receiving connectors 506 individually associated with the ground surface contact pads, channels, or lines. The one or more daughter boards 204 may be coupled to the midplane or backplane 202 through a lead frame connector 504. The lead frame connectors 504 may include the pins arranged in an array. The receiving connectors 506 may include blind fasteners. There may be flanges for the blind fasteners to hold the lead frame connectors 504 to the receiving connectors 506.

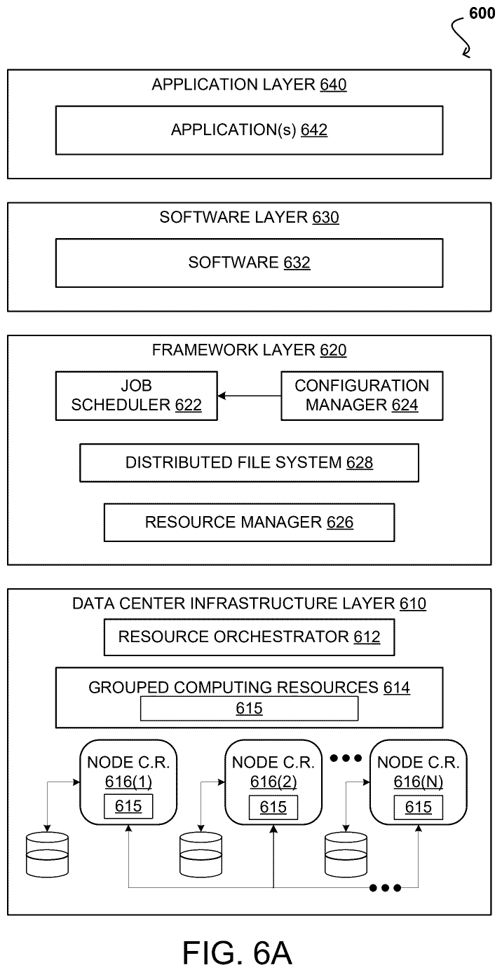

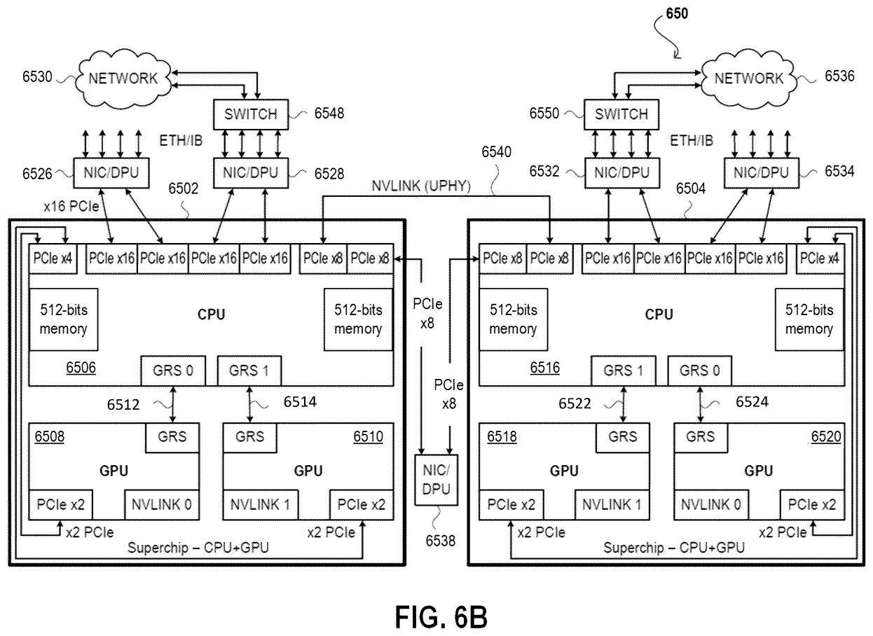

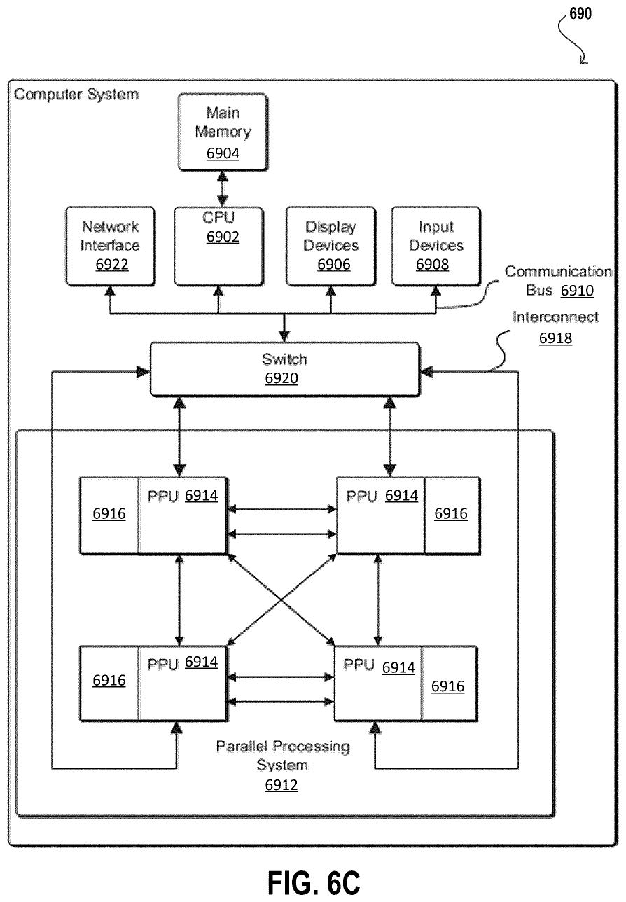

FIG. 6A illustrates an example datacenter 600, in which at least one embodiment may be used. In at least one embodiment, datacenter 600 includes a datacenter infrastructure layer 610, a framework layer 620, a software layer 630, and an application layer 640. FIG. 6A illustrates an example datacenter 600, in which at least one embodiment may be used. In at least one embodiment, datacenter 600 includes a datacenter infrastructure layer 610, a framework layer 620, a software layer 630, and an application layer 640. A datacenter 600 may include one or more racks, such as described in connection with at least FIGS. 4 and 5. The racks may include one or more server trays. There may be one or more electronic components in the one or more server trays to perform at least part of a workload in the datacenter. The racks and server trays may be represented by at least the datacenter infrastructure layer 610. The electronic components may be presented by the node computing resources 616(1)-616(N) that may be subject to cooling using cold plates.

In at least one embodiment, as shown in FIG. 6A, datacenter infrastructure layer 610 may include a resource orchestrator 612, grouped computing resources 614, and node computing resources (“node C.R.s”) 616(1)-616(N), where “N” represents any whole, positive integer. In at least one embodiment, node C.R.s 616(1)-616(N) may include, but are not limited to, any number of central processing units (“CPUs”) or other processors (including accelerators, field programmable gate arrays (FPGAs), graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R.s from among node C.R.s 616(1)-616(N) may be a server having one or more of above-mentioned computing resources.

In at least one embodiment, grouped computing resources 614 may include separate groupings of node C.R.s housed within one or more racks (not shown), or many racks housed in datacenters at various geographical locations (also not shown). Separate groupings of node C.R.s within grouped computing resources 614 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 612 may configure or otherwise control one or more node C.R.s 616(1)-616(N) and/or grouped computing resources 614. In at least one embodiment, resource orchestrator 612 may include a software design infrastructure (“SDI”) management entity for datacenter 600. In at least one embodiment, resource orchestrator may include hardware, software or some combination thereof.

In at least one embodiment, as shown in FIG. 6A, framework layer 620 includes a job scheduler 622, a configuration manager 624, a resource manager 626 and a distributed file system 628. In at least one embodiment, framework layer 620 may include a framework to support software 632 of software layer 630 and/or one or more application(s) 642 of application layer 640. In at least one embodiment, software 632 or application(s) 642 may respectively include web-based service software or applications, such as those provided by Amazon Web Services, Google Cloud and Microsoft Azure. In at least one embodiment, framework layer 620 may be, but is not limited to, a type of free and open-source software web application framework such as Apache Spark™ (hereinafter “Spark”) that may use distributed file system 628 for large-scale data processing (e.g., “big data”). In at least one embodiment, job scheduler 622 may include a Spark driver to facilitate scheduling of workloads supported by various layers of datacenter 600. In at least one embodiment, configuration manager 624 may be capable of configuring different layers such as software layer 630 and framework layer 620 including Spark and distributed file system 628 for supporting large-scale data processing. In at least one embodiment, resource manager 626 may be capable of managing clustered or grouped computing resources mapped to or allocated for support of distributed file system 628 and job scheduler 622. In at least one embodiment, clustered or grouped computing resources may include grouped computing resources 614 at datacenter infrastructure layer 610. In at least one embodiment, resource manager 626 may coordinate with resource orchestrator 612 to manage these mapped or allocated computing resources.

In at least one embodiment, software 632 included in software layer 630 may include software used by at least portions of node C.R.s 616(1)-616(N), grouped computing resources 614, and/or distributed file system 628 of framework layer 620. The one or more types of software may include, but are not limited to, Internet web page search software, e-mail virus scan software, database software, and streaming video content software.

In at least one embodiment, application(s) 642 included in application layer 640 may include one or more types of applications used by at least portions of node C.R.s 616(1)-616(N), grouped computing resources 614, and/or distributed file system 628 of framework layer 620. One or more types of applications may include, but are not limited to, any number of a genomics application, a cognitive compute, and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 624, resource manager 626, and resource orchestrator 612 may implement any number and type of self-modifying actions based on any amount and type of data acquired in any technically feasible fashion. In at least one embodiment, self-modifying actions may relieve a datacenter operator of datacenter 600 from making possibly bad configuration decisions and possibly avoiding underused and/or poor performing portions of a datacenter.

In at least one embodiment, datacenter 600 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to datacenter 600. In at least one embodiment, trained machine learning models corresponding to one or more neural networks may be used to infer or predict information using resources described above with respect to datacenter 600 by using weight parameters calculated through one or more training techniques described herein.

In at least one embodiment, datacenter may use CPUs, application-specific integrated circuits (ASICs), GPUs, FPGAs, DPUs, QPUs or PPUs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 615 are used to perform inferencing and/or training operations associated with one or more embodiments. In at least one embodiment, inference and/or training logic 615 may be used in system FIG. 6A for inferencing or predicting operations based, at least in part, on weight parameters calculated using neural network training operations, neural network functions and/or architectures, or neural network use cases described herein.

FIG. 6B is a block diagram that schematically illustrates a computing system that may be a datacenter or a High-Performance Computing (HPC) cluster, in which at least one embodiment from FIGS. 1A-5 may be used. The computing system 650 may include a plurality of subsystems, e.g., multiple processing devices coupled to each other, multiple network devices, and multiple networks, according to at least some embodiments. The computing system 650 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 650 and to one or more external networks 6530, 6536. In the present example, computing system 650 comprises a packet switch 6548 that connects NIC/DPU 6528 to external network 6530, and a packet switch 6550 that connects NIC/DPU 6532 to external network 6536.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 650 can include one or more CPUs and one or more GPUs.

FIG. 6B also demonstrates an example architecture of a multi-GPU architecture. As illustrated in the figure, computing system 650 includes a processing device 6502 with a multi-GPU architecture. In particular, processing device 6502 may be a system-on-chip and includes multiple subsystems such as a CPU 6506, a GPU 6508, and a GPU 6510. CPU 6506 can be coupled to GPU 6508 via a die-to-die (D2D) or chip-to-chip (C2C) interconnect 6512, such as a Ground-Referenced Signaling interconnect (GRS interconnect). CPU 6506 can be coupled to GPU 6510 via a D2D or C2C interconnect 6514. CPU 6506 can also couple to GPU 6508 and GPU 6510 via PCIe interconnects.

CPU 6506 can be coupled to one or more NICs or DPUs, which are coupled to one or more networks. For example, as illustrated in FIG. 6B, CPU 6506 is coupled to a first NIC/DPU 6526, which is coupled to an external network 6530. CPU 6506 is also coupled to a second NIC/DPU 6528, which is coupled to external network 6530 via packet switch 6548. NIC/DPU 6526 and NIC/DPU 6528 can be coupled to external network 6530 over Ethernet (ETH), NVLINK or InfiniBand (IB) connections, for example.

Computing system 650 also includes a processing device 6504 with a multi-GPU architecture. In particular, processing device 6504 includes multiple subsystems including a CPU 6516, a GPU 6518, and a GPU 6520. CPU 6516 can be coupled to GPU 6518 via a D2D or C2C interconnect 6522. CPU 6516 can be coupled to GPU 6520 via a D2D or C2C interconnect 6524. CPU 6516 can also couple to GPU 6518 and GPU 6520 via PCIe interconnects. CPU 6516 can be coupled to one or more NICs or DPUs, which are coupled to one or more networks. For example, as illustrated in FIG. 6B, CPU 6516 is coupled to a first NIC/DPU 6532, which is coupled to an external network 6536. CPU 6516 is also coupled to a second NIC/DPU 6534, which is coupled to the external network 6536 via packet switch 6550. NIC/DPU 6532 and NIC/DPU 6534 can be coupled to the external network 6536 over Ethernet (ETH), NVLINK or InfiniBand (IB) connections.

In at least one embodiment, processing device 6502 and processing device 6504 can communicate with each other via a NIC/DPU 6538, such as over PCIe interconnects. Processing device 6502 and processing device 6504 can also communicate with each other over a high-bandwidth communication interconnects 6540, such as an NVLink interconnect or other high-speed interconnects. The packet switches in FIG. 6B may comprise, for example, Nvidia Quantum-2 switches. The NICs/DPUs in the figure may comprise, for example, Nvidia Bluefield DPUs.

In various embodiments, any of the network devices of the computing system 650, e.g., any of NICs/DPUs 6526, 6528, 6532, 6534 and 6538, and/or any of packet switches 6548 and 6550, may include a shaped leak sensor that can match a geometry around components and features in the computing system 650 and that can be communicatively coupled together to extend leak detection capabilities.

FIG. 6C illustrates a computer system, according to at least one example, in which at least one embodiment from FIGS. 1A-6B and 7 may be used. In at least one embodiment, computer system 690 is configured to implement various processes and methods described throughout this disclosure.

In at least one embodiment, computer system 690 comprises, without limitation, at least one central processing unit (“CPU”) 6902 that is connected to a communication bus 6910 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 690 includes, without limitation, a main memory 6904 and control logic (e.g., implemented as hardware, software, or a combination thereof) and data are stored in main memory 6904 which may take form of random access memory (“RAM”). In at least one embodiment, a network interface subsystem (“network interface”) 6922 provides an interface to other computing devices and networks for receiving data from and transmitting data to other systems from computer system 690.

In at least one embodiment, computer system 690, in at least one embodiment, includes, without limitation, input devices 6908, parallel processing system 6912, and display devices 6906 which can be implemented using a conventional cathode ray tube (“CRT”), liquid crystal display (“LCD”), light emitting diode (“LED”), plasma display, or other suitable display technologies. In at least one embodiment, user input is received from input devices 6908 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 6904 and/or secondary storage. Computer programs, if executed by one or more processors, enable computer system 690 to perform various functions in accordance with at least some embodiments. Main memory 6904, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 6902; parallel processing system 6912; an integrated circuit capable of at least a portion of capabilities of both CPU 6902; parallel processing system 6912; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 690 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 6912 includes, without limitation, a plurality of parallel processing units (“PPUs”) 6914 and associated memories 6916. In at least one embodiment, PPUs 6914 are connected to a host processor or other peripheral devices via an interconnect 6918 and a switch 6920 or multiplexer. In at least one embodiment, parallel processing system 6912 distributes computational tasks across PPUs 6914 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 6914, although such shared memory may incur performance penalties relative to use of local memory and registers resident to a PPU 6914. In at least one embodiment, operation of PPUs 6914 is synchronized through use of a command such as_syncthreads( ), wherein all threads in a block (e.g., executed across multiple PPUs 6914) to reach a certain point of execution of code before proceeding.

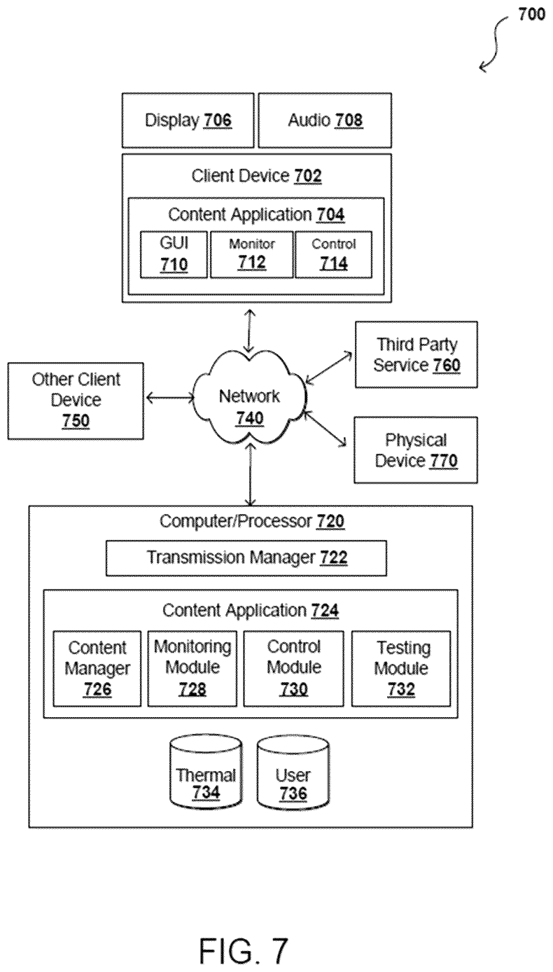

FIG. 7 illustrates an example network configuration 700 of components that can be used to implement aspects of various embodiments, such as to provide, generate, modify, encode, process, fuse, and/or transmit generated image data, calculated measurements, or other such content. In at least one embodiment, a client device 702 can generate or receive data for a session using components of a content application 704 on the client device 702 and data stored locally on that client device. In at least one embodiment, a content application 724 executing on a computer or processor 720 (e.g., a cloud server or control system) may initiate a session associated with at least one client device 702 (e.g., a vehicle or robot), as may use a session manager and user data stored in a user database 736, and can cause content such as liquid coolant or server thermal data to be selected and/or retrieved from a thermal repository 734 to be used by a testing module 732 to calculate one or more performance metrics for a monitoring module 728, which can provide flow data or thermal data to a control module 730 to control a flow or temperature, in an environment where the data is to be used to determine appropriate operation. A content manager 726 may work with these various modules to perform testing and analysis, and potentially instruct any actions to be taken in response to a performance metric failing to satisfy an operational requirement. At least a portion of this data or instructional content can be transmitted to the client device 702 and/or a physical device 770 using an appropriate transmission manager 722 to send by download, streaming, or another such transmission channel. An encoder may be used to encode and/or compress at least some of this data before transmitting to the client device 702. In at least one embodiment, the client device 702 receiving such content can provide this content to a corresponding content application 704, which may also or alternatively include a graphical user interface (GUI) 710, a flow monitor module 712, and a control module 714 for use in providing, synthesizing, rendering, compositing, modifying, or using content for presentation, navigation, control, (or other purposes) on or by the client device 702, such as may be transmitted to the physical device 770. In some embodiments, the computer/processor 720 and client device 702 may be able to communicate directly without needing to transmit data over a network 740, in order to avoid issues with latency and availability, etc. A decoder may also be used to decode data received over the network 740 for presentation via client device 702, such as imaging content or performance metrics through a display device 706 and audio, such as corresponding sounds or synthesized speech, through at least one audio playback device 708, such as speakers or headphones. In at least one embodiment, at least some of this content may already be stored on, rendered on, or accessible to client device 702 such that transmission over a network 740 is not required for at least that portion of content, such as where that content (e.g., thermal data) may have been previously downloaded or stored locally on a hard drive or optical disk. In at least one embodiment, a transmission mechanism such as data streaming can be used to transfer this content from the computer/processor 720, or user database 736, to the client device 702. In at least one embodiment, at least a portion of this content can be obtained, enhanced, and/or streamed from another source, such as a third party service 760 or other client device 750, that may also include a content application for generating, updating, enhancing, or providing map content. In at least one embodiment, portions of this functionality can be performed using multiple computing devices, or multiple processors within one or more computing devices, such as may include a combination of CPUs and GPUs (Graphics Processing Unit).

In at least one embodiment, a cold plate herein may include adjustable fins forming microchannels for fluid to flow through. In at least one embodiment, fins in a cold plate allow transfer of heat from at least one associated computing device to a fluid flowing through microchannels formed between multiple fins. In at least one embodiment, fins of a cold plate are dynamically and adjustable in real time to allow transfer of more heat from at least one computing device to a fluid that flows through a cold plate having fins. In at least one embodiment, such fins may be adjusted by a processor or processorless system based in part on a temperature determined, such as sensed, for a cold plate. In at least one embodiment, a temperature may be associated with at least one computing device, a workload of at least one computing device, or a fluid at different time periods and at an entry, and at an egress of a cold plate. In at least one embodiment, a processorless system may rely on a thermal property of at least two materials used to form fins for a cold plate so that such fins may react without a processor to cause exposure of more surface area to a fluid. In at least one embodiment, such fins may include an overlapping portion that may be caused to be exposed by action of a control mechanism or by properties of at least two materials associated together to form a fin.

In at least some of these examples, client devices can include any appropriate computing devices, as may include a desktop computer, notebook computer, set-top box, streaming device, gaming console, smartphone, tablet computer, VR headset, AR goggles, wearable computer, or a smart television. Each client device can submit a request across at least one wired or wireless network, as may include the Internet, an Ethernet, a local area network (LAN), or a cellular network, among other such options. In this example, these requests can be submitted to an address associated with a cloud provider, who may operate or control one or more electronic resources in a cloud provider environment, such as may include a datacenter or server farm. In at least one embodiment, the request may be received or processed by at least one edge server, which sits on a network edge and is outside at least one security layer associated with the cloud provider environment. In this way, latency can be reduced by allowing the client devices to interact with servers that are in closer proximity, while also improving security of resources in the cloud provider environment.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. Term “connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. Use of term “set” (e.g., “a set of items”) or “subset,” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B, and at least one of C each to be present. In addition, unless otherwise noted or contradicted by context, term “plurality” indicates a state of being plural (e.g., “a plurality of items” indicates multiple items). A plurality is at least two items but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. A set of non-transitory computer-readable storage media, in at least one embodiment, comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

Accordingly, in at least one embodiment, computer systems are configured to implement one or more services that singly or collectively perform operations of processes described herein and such computer systems are configured with applicable hardware and/or software that allow performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU, GPU, DPUs, QPUs, or PPUs. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. Terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. Obtaining, acquiring, receiving, or inputting analog and digital data can be accomplished in a variety of ways such as by receiving data as a parameter of a function call or a call to an application programming interface. In some implementations, process of obtaining, acquiring, receiving, or inputting analog or digital data can be accomplished by transferring data via a serial or parallel interface. In another implementation, process of obtaining, acquiring, receiving, or inputting analog or digital data can be accomplished by transferring data via a computer network from providing entity to acquiring entity. References may also be made to providing, outputting, transmitting, sending, or presenting analog or digital data. In various examples, process of providing, outputting, transmitting, sending, or presenting analog or digital data can be accomplished by transferring data as an input or output parameter of a function call, a parameter of an application programming interface or interprocess communication mechanism.

Although discussion above sets forth example implementations of described techniques, other architectures may be used to implement described functionality, and are intended to be within scope of this disclosure. Furthermore, although specific distributions of responsibilities are defined above for purposes of discussion, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A circuit board assembly comprising a printed circuit board (PCB) having at least two layers and a blind fastener capability provided, at least in part, by a hole through at most a first one of the at least two layers, wherein the hole is of a predetermined dimension to receive a blind fastener associated with an external component or connector and to allow the blind fastener to be anchored therein, wherein a second one of the at least two layers comprises one or more of a circuit component, an interconnect, or a further blind fastener capability which is through at most the second one of the at least two layers, and wherein the circuit component, the interconnect, or the further blind fastener capability is in an unused area that is in an opposite or offset position from the hole.

2. The circuit board assembly of claim 1, wherein the blind fastener capability defines the unused area in the opposite or offset position from the hole based in part on a radius dimension that is away from the hole, and wherein the unused area is on a surface of the second one of the at least two layers, is through the surface of the second one of the at least two layers, or is between the at least two layers of the PCB.

3. The circuit board assembly of claim 1, further comprising:
a threaded component that is embedded between the at least two layers of the PCB, the threaded component forming a further part of the blind fastener capability, wherein a stud having external threads forms the blind fastener to fasten into the threaded component to allow the blind fastener to be anchored in the blind fastener capability.

4. The circuit board assembly of claim 1, further comprising:
a material of the PCB to allow a rivet-screw having an external thread to be received into the hole, the hole being a non-threaded hole and the rivet-screw forming the blind fastener, wherein the material is further to allow the external thread of the rivet-screw to be expanded into sidewalls of the hole by circumferential expansion of the rivet-screw, wherein the expansion into the sidewalls is to allow the blind fastener to be anchored in the blind fastener capability, and wherein the rivet-screw is removable by rotation of the external thread against the sidewalls of the hole.

5. The circuit board assembly of claim 1, further comprising:
one or more deformable pins of an external connector, the one or more deformable pins to be received into the blind fastener capability and to collapse, at least in part, within the blind fastener capability, the one or more deformable pins forming the blind fastener, wherein the collapse is to allow the one or more deformable pins to be anchored within the blind fastener capability.

6. The circuit board assembly of claim 1, wherein the blind fastener is a removable or reusable fastener, and wherein the blind fastener capability is also removable or reusable to receive the blind fastener and to allow the blind fastener to be anchored therein.

7. The circuit board assembly of claim 1, wherein the PCB comprises external connectors to the blind fastener capability on the first one of the at least two layers, and comprises only the circuit components or the interconnects on the second one of the at least two layers.

8. The circuit board assembly of claim 1, wherein the PCB is a dual-sided midplane, wherein the interconnect is a copper connector within the at least two layers of the PCB, wherein the circuit component is a graphic process unit (GPU) on the second one of the at least two sides of the PCB, and wherein the copper connector and the GPU are in the unused area.

9. A blind fastener capability provided, at least in part, by a hole through at most a first one of at least two layers of a printed circuit board (PCB), wherein the hole is of a predetermined dimension to receive a blind fastener associated with an external component or connector and to allow the blind fastener to be anchored therein, wherein a second one of the at least two layers is to comprise one or more of a circuit component, an interconnect, or a further blind fastener capability which is through at most the second one of the at least two layers, and wherein the circuit component, the interconnect, or the further blind fastener capability is to be in an unused area that is defined in an opposite or offset position from the hole.

10. A silicon package comprising a printed circuit board (PCB) having at least two layers and a blind fastener capability provided, at least in part, by a hole through at most a first one of the at least two layers, wherein the hole is of a predetermined dimension to receive a blind fastener associated with an external component or connector and to allow the blind fastener to be anchored therein, wherein a second one of the at least two layers comprises one or more of a circuit component, an interconnect, or a further blind fastener capability which is through at most the second one of the at least two layers, and wherein the circuit component, an interconnect, or a further blind fastener capability is in an unused area that is in an opposite or offset position from the hole.

11. A system comprising:
a printed circuit board (PCB) comprising at least two layers and a blind fastener capability provided, at least in part, by a hole through at most a first one of the at least two layers, wherein the hole is of a predetermined dimension; and
an external component or a connector comprising a blind fastener to couple with the blind fastener capability and to allow the blind fastener to be anchored therein, wherein a second one of the at least two layers comprises one or more of a circuit component, an interconnect, or a further blind fastener capability which is through at most the second one of the at least two layers, and wherein the circuit component, the interconnect, or the further blind fastener capability is in an unused area that is in an opposite or offset position from the hole.

12. The system of claim 11, wherein the blind fastener capability defines the unused area in the opposite or offset position from the hole based in part on a radius dimension that is away from the hole, and wherein the unused area is on a surface of the second one of the at least two layers, is through the surface of the second one of the at least two layers, or is between the at least two layers of the PCB.

13. The system of claim 11, further comprising:
a threaded component that is embedded between the at least two layers of the PCB, the threaded component forming a further part of the blind fastener capability, wherein a stud having external threads forms the blind fastener to fasten into the threaded component to allow the blind fastener to be anchored in the blind fastener capability.

14. The system of claim 11, further comprising:
a material of the PCB to allow a rivet-screw having an external thread to be received into the hole, the hole being a non-threaded hole and the rivet-screw forming the blind fastener, wherein the material is further to allow the external thread of the rivet-screw to be expanded into sidewalls of the hole by circumferential expansion of the rivet-screw, wherein the expansion into the sidewalls is to allow the blind fastener to be anchored in the blind fastener capability, and wherein the rivet-screw is removable by rotation of the external threw against the sidewalls of the hole.

15. The system of claim 11, further comprising:
one or more deformable pins of an external connector, the one or more deformable pins to be received into the blind fastener capability and to collapse, at least in part, within the blind fastener capability, the one or more deformable pins forming the blind fastener, wherein the collapse is to allow the one or more deformable pins to be anchored within the blind fastener capability.

16. The system of claim 11, wherein the blind fastener is to make up the electrical connection with the pins based in part on a surface tension available within the blind fastener.

17. The system of claim 11, wherein the blind fastener is a removable or reusable fastener, and wherein the blind fastener capability is also removable or reusable to receive the blind fastener and to allow the blind fastener to be anchored therein.

18. A datacenter, comprising:
a midplane or a backplane within one or more racks in the datacenter;
at least two layers and a blind fastener capability provided in the midplane or the backplane and provided, at least in part, by a hole through at most a first one of the at least two layers, wherein the hole is of a predetermined dimension; and
an external component or a connector comprising a blind fastener to couple with the blind fastener capability and to allow the blind fastener to be anchored therein, wherein a second one of the at least two layers comprises one or more of a circuit component, an interconnect, or a further blind fastener capability which is through at most the second one of the at least two layers, and wherein the circuit component, the interconnect, or the further blind fastener capability is in an unused area that is in an opposite or offset position from the hole.

19. A method for an electrical connection, the method comprising;
preparing a printed circuit board (PCB) to comprise at least two layers;
determining a hole of a predetermined dimension to receive a blind fastener associated with an external component or connector;
forming a blind fastener capability based at least in part by the hole being provided through at most a first one of the at least two layers; and
allowing the blind fastener to be anchored into the blind fastener capability, wherein a second one of the at least two layers comprises one or more of a circuit component, an interconnect, or a further blind fastener capability which is through at most the second one of the at least two layers, and wherein the circuit component, the interconnect, or the further blind fastener capability is in an unused area that is in an opposite or offset position from the hole.

20. The method of claim 19, further comprising one or more of:
defining the unused area, for the blind fastener capability, in the opposite or offset position from the hole based in part on a radius dimension that is away from the hole, wherein the unused area is on a surface of the second one of the at least two layers, is through the surface of the second one of the at least two layers, or is between the at least two layers of the PCB;
embedding a threaded component between the at least two layers of the PCB, the threaded component forming a further part of the blind fastener capability, wherein a stud having external threads forms the blind fastener to fasten into the threaded component to allow the blind fastener to be anchored in the blind fastener capability;
using a material of the PCB to allow a rivet-screw having an external thread to be received into the hole, the hole being a non-threaded hole and the rivet-screw forming the blind fastener, wherein the material is further to allow the external thread of the rivet-screw to be expanded into sidewalls of the hole by circumferential expansion of the rivet-screw, wherein the expansion into the sidewalls is to allow the blind fastener to be anchored in the blind fastener capability, and wherein the rivet-screw is removable by rotation of the external threw against the sidewalls of the hole;
allowing one or more deformable pins of an external connector to be received into the blind fastener capability and to collapse, at least in part, within the blind fastener capability, the one or more deformable pins forming the blind fastener, wherein the collapse is to allow the one or more deformable pins to be anchored within the blind fastener capability;
allowing the blind fastener to be removable or reusable, and wherein the blind fastener capability is also removable or reusable to receive the blind fastener and to allow the blind fastener to be anchored therein;
allowing the PCB to comprise external connectors to the blind fastener capability on the first one of the at least two layers, and comprises only the circuit components or the interconnects on the second one of the at least two layers; or
allowing the PCB to be a dual-sided midplane, wherein the interconnect is a copper connector within the at least two layers of the PCB, wherein the circuit component is a graphic process unit (GPU) on the second one of the at least two sides of the PCB, and wherein the copper connector and the GPU are in the unused area.
